(19) United States
(12) Patent Application Publication
(10) Pub. No.: US 2025/0378887 A1
(43) Pub. Date: Dec. 11, 2025

(54) METHOD AND APPARATUS FOR SENSING FLASH MEMORY OUTPUT

(71) Applicant: Allegro MicroSystems, LLC, Manchester, NH (US)

(72) Inventors: Muhammad Sarwar, North Grafton, MA (US); James M. McClay, Dudley, MA (US)

(73) Assignee: Allegro MicroSystems, LLC, Manchester, NH (US)

(21) Appl. No.: 18/738,149

(22) Filed: Jun. 10, 2024

(51) Int. Cl. G11C 16/26; G11C 7/10; G11C 16/08

(52) U.S. Cl. CPC G11C 16/26; G11C 7/1084; G11C 16/08

(57) ABSTRACT

A read amplifier, comprising: a transistor having a first terminal and a second terminal, the second terminal being coupled to a sense node, the transistor being arranged to: (i) receive, on the second terminal, a data signal that is generated at least in part by a memory matrix, and (ii) output, on the sense node, an amplified data signal; and a feedback circuit arranged to generate, based at least in part on the data signal, a feedback signal that is applied at a gate of the transistor; and a pre-charge circuit that is configured to pre-charge the sense node to a predetermined value, such that, after the sense node is pre-charged, a voltage at the sense node settles at a value corresponding to the amplified data signal.

### BACKGROUND

Flash memory serves as a crucial component in a wide array of integrated devices, including sensor devices. Its non-volatile nature allows for the retention of data without a power source, making it ideal for storing information gathered over extended periods. This capability enables sensor devices to collect and store data without the need for constant power supply, enhancing their efficiency and usability in various applications such as environmental monitoring, healthcare, and industrial automation. Furthermore, the compact size and robustness of flash memory make it suitable for integration into small-scale sensor devices deployed in diverse environments.

### SUMMARY

According to aspects of the disclosure, a read amplifier is provided, comprising: a transistor having a first terminal and a second terminal, the second terminal being coupled to a sense node, the transistor being arranged to: (i) receive, on the second terminal, a data signal that is generated at least in part by a memory matrix, and (ii) output, on the sense node, an amplified data signal; and a feedback circuit arranged to generate, based at least in part on the data signal, a feedback signal that is applied at a gate of the transistor; and a pre-charge circuit that is configured to pre-charge the sense node to a predetermined value, such that, after the sense node is pre-charged, a voltage at the sense node settles at a value corresponding to the amplified data signal.

According to aspects of the disclosure, a read amplifier is provided, comprising: a transistor having a first terminal and a second terminal, the second terminal being coupled to a sense node, the transistor being arranged to: (i) receive, on the second terminal, a data signal that is generated at least in part by a memory matrix, and (ii) output, on the sense node, an amplified data signal; and a pre-charge circuit that is configured to pre-charge the sense node to a predetermined value, such that, after the sense node is pre-charged, a voltage at the sense node settles at a value corresponding to the amplified data signal.

According to aspects of the disclosure, a system is provided, comprising: a flash memory; a transistor having a first terminal and a second terminal, the second terminal being coupled to a sense node, the transistor being arranged to: (i) receive, on the second terminal, a data signal that is generated at least in part by the flash memory, and (ii) output, on the sense node, an amplified data signal; a pre-charge circuit that is configured to pre-charge the sense node to a predetermined value, such that, after the sense node is pre-charged, a voltage at the sense node settles at a value corresponding to the amplified data signal; and a buffer memory having a data input terminal that is coupled to the sense node, the buffer memory being configured to buffer the amplified data signal.

### BRIEF DESCRIPTION OF THE DRAWINGS

The foregoing features may be more fully understood from the following description of the drawings in which:

FIG. 1A is a diagram of an example of a flash memory device, according to aspects of the disclosure;

FIG. 1B is a diagram of an example of a read amplifier, according to aspects of the disclosure;

FIG. 2 is a waveform diagram illustrating aspects of the operation of the read amplifier of FIG. 1A;

FIG. 3 is a waveform diagram illustrating aspects of the operation of the read amplifier of FIG. 1A;

FIG. 4 is a diagram of an example of a read amplifier, according to the prior art; and

FIG. 5 is a diagram of an example of a sensor, according to aspects of the disclosure.

### DETAILED DESCRIPTION

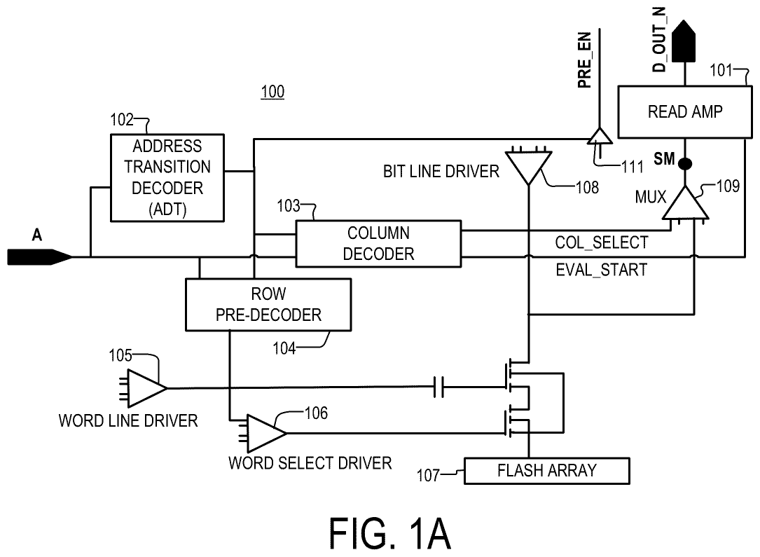

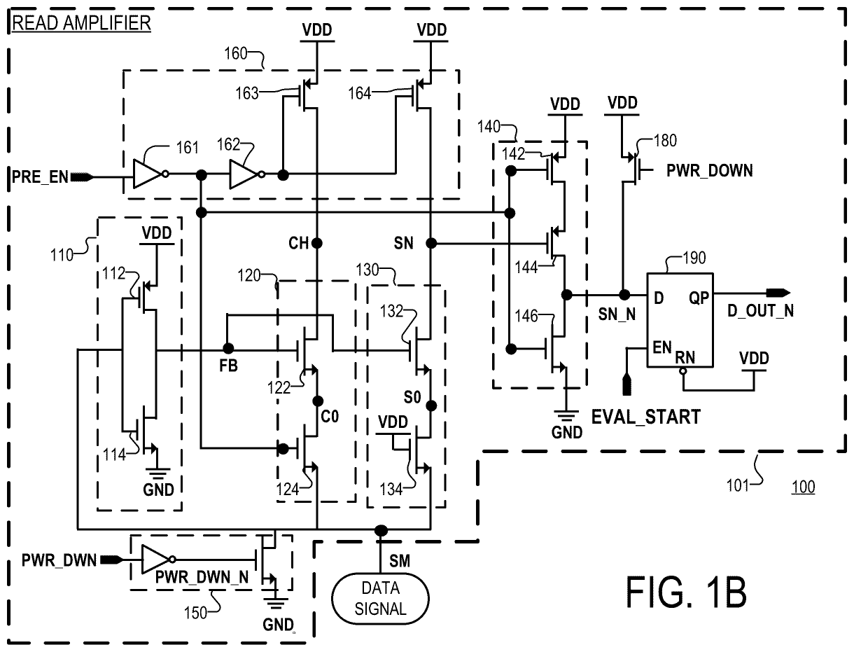

FIG. 1A is a diagram of an example of a flash memory device 100, according to aspects of the disclosure. As illustrated, the flash memory device 100 may include a read amplifier 101, an address transition decoder (ATD) 102, a column decoder 103, a row pre-decoder 104, a word line driver 105, a word select driver 106, a flash array 107, a bit line driver 108, a multiplexer 109, and a circuit 111.

The read amplifier 101 may be configured to amplify a data signal that is output by flash array 107. The signal may be received at a node SM (also shown in FIG. 1B). The structure and operation of the read amplifier 101 are discussed further below with respect to FIG. 1B.

ADT 102 may include circuitry that is configured to decode the address, as specified by an address signal A, to a specific memory cell in the flash array 107. The flash array 107 may be implemented as a memory matrix including a plurality of NAND gates and/or in any other suitable manner. The ADT 102 may receive address signal A from a memory controller or external interface and activate the appropriate cell in the flash array 107 for data access. In addition, ADT 102 may generate a pulse whenever there is a transition in address signal A. According to the present disclosure, ADT 102 is used to generate a pulse, which triggers a pre-charge of the read amplifier 101, when the value of the address signal A changes. More specifically, circuit 111 may detect the pulse and change the state of a signal PRE_EN for a predetermined amount of time. According to the present example, circuit 111 may transition the signal PRE_EN from logic-high to logic-low for a predetermined period, after which circuit 111 transitions the PRE_EN signal back to logic-high.

Column decoder 103 may be configured to supply a signal COL_SELECT to the multiplexer 119, which selects a column in the output of the flash array 107. In addition, column decoder 103 may be configured to supply a signal EVAL_START, which causes a latch in the read amplifier 101 (e.g., latch 190, shown in FIG. 1B) to store the output of the flash array 107.

The row pre-decoder 104 may include circuitry responsible for assisting in the selection of a line in the flash array 107 that is specified by the address signal A. The word select driver 106 may be configured to receive the output of row pre-decoder 104 and select a word line that is specified by the output of row pre-decoder 104. The word line driver 105 may be configured to select a portion of flash array 170 to reduce the loading effect on the column lines of flash array 107. The bit line driver 108 may be configured to sense and amplify the output of the flash array 107, ensuring that data can be accurately retrieved from the flash array 107. The multiplexer 109 may be configured to provide a bit that is selected by column decoder 103, to the read amplifier 101. Under the nomenclature of the present disclosure, the provided bit is also referred to as a “data signal” and it is applied at node SM, as shown.

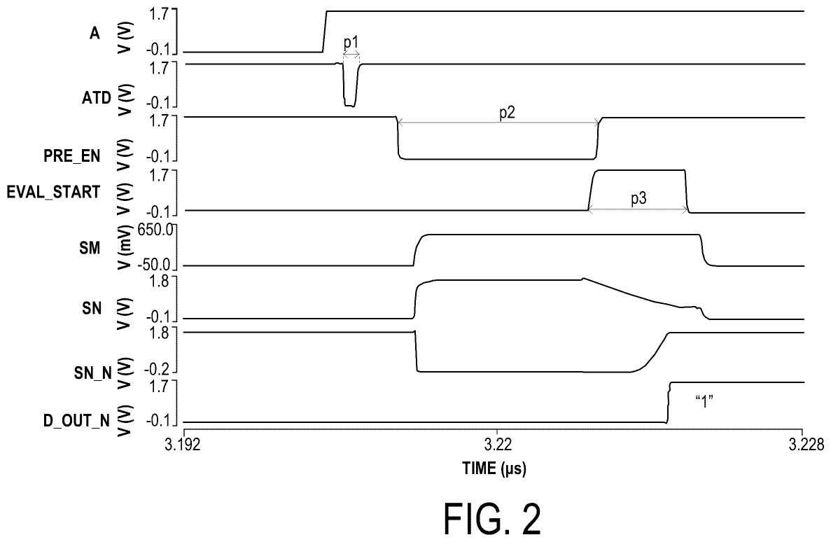

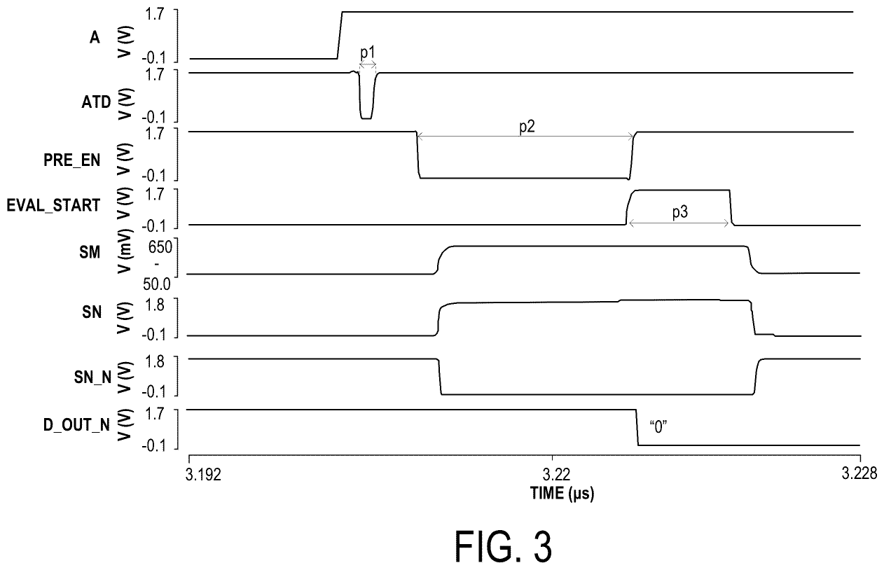

The read amplifier 101 may feature a voltage-limiting cascade with negative feedback and a pre-charging scheme. The integration of these features into read amplifier 101 results in faster reading times than conventional circuits. As illustrated in FIG. 1B, the read amplifier 101 may include a feedback circuit 110, a conditioning circuit 120, an amplifier circuit 130, an inverter circuit 140, a ground disconnect circuit 150, a pre-charge circuit 160, a transistor 180, and a latch 190. Pre-charge circuit 160 may include an inverter 161, an inverter 162, a PMOS transistor 163, and a PMOS transistor 164. Inverter 161 may receive a signal PRE_EN as input. Inverter 162 may receive as input the output of inverter 161. The output of inverter 162 may be applied at the gates of transistors 163 and 164, as shown. The respective sources of transistors 163 and 163 may be coupled to a voltage source VDD. The drain of transistor 163 may be coupled to a node CH. The drain of transistor 164 may be coupled to a node SN. In operation, the pre-charge circuit 160 may raise the voltage at node SN to a predetermined value, which in turn shortens the time it takes for transistor 132 to amplify the data signal that is output by the flash array 107 (shown in FIG. 1A) on node SM. According to the present example, the node SN is pre-charged to a logic-high value. However, the present disclosure is not limited thereto. The pre-charging occurs during a period p2 (shown in FIGS. 2-3).

The feedback circuit 110 may include a complementary metal-oxide-semiconductor (CMOS) transistor 112 and an N-type metal-oxide-semiconductor (NMOS) transistor 114. The drain of transistor 112 may be coupled to the drain of transistor 114 at node FB. The gates of transistors 112 and 114 may be coupled to node SM. The source of transistor 112 may be coupled to a voltage source VDD and the source of transistor 114 may be coupled to ground.

The conditioning circuit 120 may include NMOS transistors 112 and 124. The drain of transistor 122 may be coupled to the drain of a CMOS transistor 166, the source of transistor 122 may be coupled to node CH, and the gate of transistor 122 may be coupled to node FB. The source of transistor 124 may be coupled to node SM, and the gate of transistor 124 may be coupled to the output of inverter 161. The conditioning circuit 120 may be configured to reduce the capacitance on node SN to speed up both the pre-charge and sensing phases. The pre-charge and sensing phases correspond to periods p2 and p3 in FIGS. 2-3.

The amplifier circuit 130 may include an NMOS transistor 132 and an NMOS transistor 134. The drain of transistor 132 may be coupled to node SN, the gate of transistor 132 may be coupled to node FB, and the source of transistor 132 may be coupled to the drain of transistor 134. The source of transistor 134 may be coupled to node SM, and the gate of transistor 134 may be coupled to the voltage source VDD. The amplifier circuit 130 is provided as an example only. It will be understood that the amplifier circuit 130 may include any suitable set of one or more transistors. Although, in the present example, transistor 132 is an NMOS transistor, alternative implementations are possible in which transistor 132 can be any suitable type of transistor (e.g., PMOS, MOSFET, etc.). Although, in the present example, transistor 134 is an NMOS transistor, alternative implementations are possible in which transistor 134 can be any suitable type of transistor (e.g., PMOS, MOSFET, etc.).

The inverter circuit 140 may include PMOS transistors 142 and 144 and an NMOS transistor 146. The source of transistor 142 may be coupled to the voltage source VDD, the gate of transistor 142 may be coupled to the output of inverter 161, and the drain of transistor 142 may be coupled to the source of transistor 144. The gate of transistor 144 may be coupled to node SN and the drain of transistor 144 may be coupled to node SN_N. The drain of transistor 146 may be coupled to node SN_N, the gate of transistor 146 may be coupled to the output of inverter 161, and the source of transistor 146 may be coupled to ground.

Transistor 180 may be coupled between the voltage source VDD and the node SN_N, as shown. The gate of transistor 180 may be arranged to receive a signal PWR_DWN to pull SN_N node to VDD level to eliminate any possibility of floating gate. The ground disconnect circuit 150 may be configured to disconnect circuits 110-130 from ground in response to a signal PWR_DWN. The ground disconnect circuit may include an inverter 151 that is arranged to invert signal PWR_DOWN and apply the inverted signal at the gate of a NMOS transistor, as shown.

Latch 190 may be a D latch. The data terminal D of the latch 190 may be coupled to node SN_N. The non-inverted output QP of the latch 190 is herein referred to as signal D_OUT. The power supply terminal RN of the latch 190 may be coupled to the voltage source VDD.

In operation, node SN may be pre-charged to a logic-high during the pre-charge stage (e.g., period p2 in FIGS. 2-3), while node SN_N is pre-charged to the low state. During the pre-charge phase, the voltage at node SM will rise towards the limit voltage, which, depending on physical location, temperature, and supply voltage, lies between 500 mV and 800 mV. It is important to note that the transistor 124 is operating close to, or already inside, the sub-threshold region at the end of the pre-charge phase. The feedback circuit 110 controlling the gate of transistor 132 is operating in the linear region of transistor 132 so that the feedback circuit 110 and the amplifier circuit 130 together provide high amplification. As noted above, the conditioning circuit 120 may be configured to reduce the capacitance on node SN to speed up both the pre-charge and sensing phases.

FIG. 2 is a waveform diagram illustrating aspects of the operation of read amplifier 101 when the value of ‘1’ is read from the flash array 107. As illustrated, when the address signal A transitions from logic-high to logic-low, the signal output by ADT 102 may dip for a period p1, which in turn causes circuit 111 (shown in FIG. 1A), to set the signal PRE_EN to logic-low for a period p2. While the signal PRE_EN is set to logic-low, transistors 163 and 164 are turned on, which causes the voltage at node SN to rise to logic-high. Afterwards, signal PRE_EN returns to logic-high and the signal EVAL_START is set to logic-high for a period p3. While the signal EVAL_START is at logic-high, the inverted amplified output SN_N of inverter circuit 140 is latched into latch 190. At the end of period p3, when signal EVAL_START returns to logic-low, the signal D_OUT assumes the value of the data signal that is output from the flash array 107. As used throughout the disclosure, when permitted by context, the term “data signal” shall refer to either the non-inverted version of the data signal or the inverted version of the data signal. In other words, the term “data signal” may refer to any signal that is generated, at least in part, based on the raw output of the flash array 107. In the example of FIG. 1B, the term data signal may refer to any of the output of any of circuits 130 and 140 and/or the latch 190.

FIG. 3 is a waveform diagram illustrating aspects of the operation of read amplifier 101 when the value of ‘0’ is read from the flash array 107. As illustrated, when address signal A transitions from logic-high to logic-low, the signal output by ADT 102 may dip for a period p1, which in turn causes circuit 111 (shown in FIG. 1A), to set the signal PRE_EN to logic-low for a period p2. While the signal PRE_EN is set to logic-low, transistors 163 and 164 are turned on, which causes the voltage at node SN to rise to a logic-high value. Afterwards, signal PRE_EN returns to logic-high and the signal EVAL_START is set to logic-high for a period p3. While the signal EVAL_START is at logic-high, the inverted amplified output SN_N of inverter circuit 140 is latched into latch 190. At the end of period p3, when signal EVAL_START returns to logic-low, the signal D_OUT assumes the value of the data signal that is output from the flash array 107.

It is noted that it is difficult for FIGS. 2-3 to describe, based on the plot of signal SN, whether a cell is programmed or not, since the decision, within the read amplifier 101, of whether a memory cell is erased or programmed is determined by the current flow. After the end of pre-charging period p2, in the cell sensing period p3, the voltage on SN will strongly depend on the state of the addressed NVM cell. For a programmed cell drawing a current of several microamperes, SN will be discharged rapidly until its voltage is about equal to that of SM. As the voltage of SM will also drop slightly in the process, the feedback circuit 110 will provide a higher gate voltage to transistor 122, whose improved conductance will increase the current flowing out of SN, accelerating the discharge. As the voltage at node SN drops, transistor 144 becomes conducting and pulls up the node SN_N, providing a digital high level at the input of the latch 190.

If, on the other hand, the cell is erased, the only current drawn from the sense node SN is due to the remaining voltage difference between nodes SN and SM. At the end of pre-charge period p2, this current will be less than 1 uA, in some implementations. As charge is slowly transferred between nodes SN and SM, the voltage on SM will rise, and the falling output voltage on SN and falling output voltage of the feedback circuit 110 throttles the current flow, decelerating the discharge of SN. So while the voltage of SN will inevitably fall, this process is far faster for a programmed cell than for an erased one. The two states can be distinguished by latching the state of the SN_N node at a point in time when programmed cells already have caused a high state on SN_N and erased cells have not yet caused a current flow into SN_N.

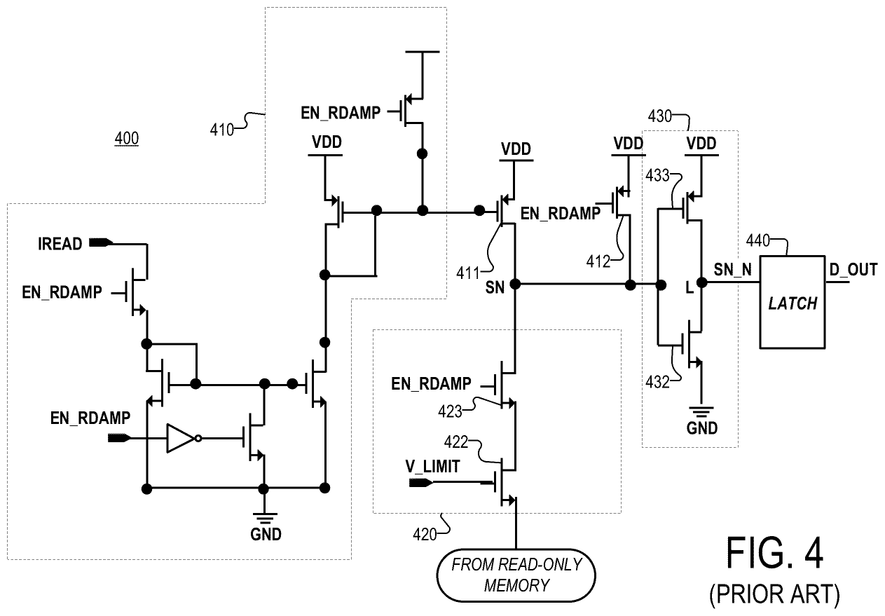

FIG. 4 is a diagram of an example of a read amplifier 400, according to the prior art. FIG. 4 is provided for the purpose of contrasting the read amplifier 400 with the read amplifier 101 and identifying features in read amplifier 101 that are not present in read amplifier 400.

According to the example of FIG. 4, the amplifier 400 may include a current source 410, an amplifier circuit 420, an inverter 430, a latch 440, a PMOS transistor 411, and a PMOS transistor 412. Current source 410 may be configured as shown. Current source 410 may be coupled to a voltage source VDD and arranged to receive signal EN_RDAMP and a signal IREAD. EN_RDAMP signal enables the read sense amplifier and IREAD is bias read current for sense amplifier.

As illustrated, the amplifier circuit 420 may include an NMOS transistor 422 and an NMOS transistor 423. The source of transistor 422 may be arranged to receive the output of a read-only memory and the drain of transistor 422 may be coupled to the source of transistor 423. The drain of transistor 423 may be coupled to a node SN. Signal EN_RDAMP may be applied at the gate of transistor 423 and a signal V_LIMIT may be applied at the gate of transistor 422.

The source of transistor 411 may be coupled to the voltage source VDD. The drain of transistor 411 may be coupled to node SN, and the gate of transistor 411 may be coupled to the output of current source 410. The source of transistor 412 may be coupled to the voltage source VDD. The drain of transistor 412 may be coupled to node SN. The gate of transistor 412 may be arranged to receive signal EN_RDAMP. Inverter 430 may include a PMOS transistor 432 and an NMOS transistor 433. The inverter 430 may receive as input the signal that is applied at node SM and output an inverted signal at a node L. The gate of transistor 432 may be coupled to node SN. The source of transistor 432 may be coupled to ground. The drain of transistor 432 may be coupled to node L. The gate of transistor 433 may be coupled to node SN. The source of transistor 433 may be coupled to the voltage source VDD. The drain of transistor 433 may be coupled to node L. Latch 440 may be arranged to buffer the output of the inverter 413 and output it as a signal D_OUT.

There are several distinctions between read amplifier 101 and read amplifier 400. Unlike read amplifier 400, read amplifier 101 includes a conditioning circuit 120 and a feedback circuit 110, which together apply a feedback signal to amplifier circuit 130, which helps pre-charge the node SN before the output of the flash array 107 is latched. Moreover, unlike read amplifier 400, read amplifier 101 includes a conditioning circuit 120, which may be arranged to reduce the capacitance on node SN.

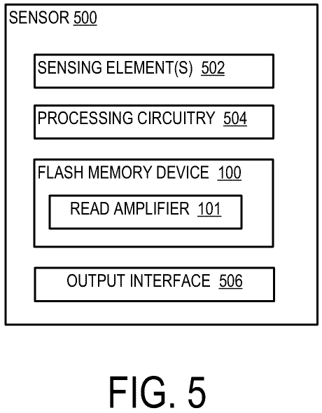

FIG. 5 is a diagram of a sensor 500, according to aspects of the disclosure. FIG. 5 is provided to illustrate one of many possible applications for the flash memory device 100 (shown in FIG. 1A), and the read amplifier 101 in particular (shown in FIG. 1B). The sensor 500 may include any suitable type of sensor. For example, the sensor 500 may include a magnetic field sensor (e.g., a position sensor, a current sensor, etc.), an optical sensor, a temperature sensor, a pressure sensor, a humidity sensor, a motion sensor, a light sensor, an infrared sensor, a gas sensor, a flow sensor, a biometric sensor, a force sensor, and/or any suitable type of sensor. The sensor 500 may include one or more sensing elements 502, a processing circuitry 504, the flash memory device 100, and an output interface 506. The sensing elements 502 may include one or more magnetic field sensing elements, pressure sensing elements, humidity sensing elements, temperature sensing elements, light sensing elements, and/or any other suitable type of sensing elements. The processing circuitry 504 may include any suitable type of processing circuitry. By way of example, the processing circuitry 504 may include one or more amplifiers, one or more digital-to-analog converters (DACs), one or more analog-to-digital converters (ADCs), a general purpose processor, a special purpose processor, a CORDIC processor, and/or any other suitable type of processing circuitry. The output interface 506 may include any suitable type of output interface, such as an analog voltage output interface, analog current output interface, a digital output interface (e.g., an I2C or SPI interface, etc.), a serial communications interface, or a wireless communications interface. The present disclosure is not limited to any specific type of communications interface or processing circuitry being present in the sensor 500.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., a addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

According to the present disclosure, a magnetic field sensing element can include one or more magnetic field sensing elements, such as Hall effect elements, magnetoresistance elements, or magnetoresistors, and can include one or more such elements of the same or different types. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A read amplifier, comprising:
a transistor having a first terminal and a second terminal, the second terminal being coupled to a sense node, the transistor being arranged to: (i) receive, on the second terminal, a data signal that is generated at least in part by a memory matrix, and (ii) output, on the sense node, an amplified data signal; and
a feedback circuit arranged to generate, based at least in part on the data signal, a feedback signal that is applied at a gate of the transistor; and
a pre-charge circuit that is configured to pre-charge the sense node to a predetermined value, such that, after the sense node is pre-charged, a voltage at the sense node settles at a value corresponding to the amplified data signal.

2. The read amplifier of claim 1, wherein the predetermined value includes a logic-high value, the first terminal includes a source of the transistor, and the second terminal includes a drain of the transistor.

3. The read amplifier of claim 1, wherein:
the pre-charge circuit is configured to pre-charge the sense node in response to a pulse in an address signal,
the pulse signals a transition in the address signal, the address signal identifying a cell in the memory matrix whose value is desired to be read, and
the data signal indicates the value of the identified cell.

4. The read amplifier of claim 1, wherein pre-charging the sense node increases, on at least some occasions, a speed at which the voltage at the sense node settles at the value corresponding to the amplified data signal.

5. The read amplifier of claim 1, wherein the output node is coupled to a latch, and pre-charging the sense node increases, on at least some occasions, a speed at which the value corresponding to the amplified data signal is stored in the latch.

6. The read amplifier of claim 1, wherein, the pre-charge circuit is configured to pre-charge the sense node during a period in which the data signal is rising to a limit voltage.

7. The read amplifier of claim 1, further comprising a conditioning circuit that is configured to reduce a capacitance on the sense node.

8. The read amplifier of claim 1, wherein the memory matrix includes a flash array and the transistor is part of an amplification circuit.

9. A read amplifier, comprising:
a transistor having a first terminal and a second terminal, the second terminal being coupled to a sense node, the transistor being arranged to: (i) receive, on the second terminal, a data signal that is generated at least in part by a memory matrix, and (ii) output, on the sense node, an amplified data signal; and
a pre-charge circuit that is configured to pre-charge the sense node to a predetermined value, such that, after the sense node is pre-charged, a voltage at the sense node settles at a value corresponding to the amplified data signal.

10. The read amplifier of claim 9, wherein the predetermined value includes a logic-high value, the first terminal includes a source of the transistor, and the second terminal includes a drain of the transistor.

11. The read amplifier of claim 9, wherein:
the pre-charge circuit is configured to pre-charge the sense node in response to a pulse in an address signal,
the pulse signals a transition in the address signal, the address signal identifying a cell in the memory matrix whose value is desired to be read, and
the data signal indicates the value of the identified cell.

12. The read amplifier of claim 9, wherein pre-charging the sense node increases, on at least some occasions, a speed at which the voltage at the sense node settles at the value corresponding to the amplified data signal.

13. The read amplifier of claim 9, wherein the output node is coupled to a latch, and pre-charging the sense node increases, on at least some occasions, a speed at which the value corresponding to the amplified data signal is stored in the latch.

14. The read amplifier of claim 9, wherein, the pre-charge circuit is configured to pre-charge the sense node during a period in which the data signal is rising to a limit voltage.

15. The read amplifier of claim 9, further comprising a conditioning circuit that is configured to reduce a capacitance on the sense node.

16. The read amplifier of claim 9, wherein the memory matrix includes a flash array and the transistor is part of an amplification circuit.

17. The read amplifier of claim 9, further comprising a feedback circuit arranged to generate, based at least in part on the data signal, a feedback signal that is applied at a gate of the transistor.

18. A system, comprising:
a flash memory;
a transistor having a first terminal and a second terminal, the second terminal being coupled to a sense node, the transistor being arranged to: (i) receive, on the second terminal, a data signal that is generated at least in part by the flash memory, and (ii) output, on the sense node, an amplified data signal;
a pre-charge circuit that is configured to pre-charge the sense node to a predetermined value, such that, after the sense node is pre-charged, a voltage at the sense node settles at a value corresponding to the amplified data signal; and
a buffer memory having a data input terminal that is coupled to the sense node, the buffer memory being configured to buffer the amplified data signal.

19. The system of claim 18, wherein the predetermined value includes a logic-high value, the first terminal includes a source of the transistor, and the second terminal includes a drain of the transistor.

20. The system of claim 18, wherein:
the pre-charge circuit is configured to pre-charge the sense node in response to a pulse in an address signal,
the pulse signals a transition in the address signal, the address signal identifying a cell in the flash memory whose value is desired to be read, and
the data signal indicates the value of the identified cell.

21. The system of claim 18, wherein pre-charging the sense node increases, on at least some occasions, a speed at which the voltage at the sense node settles at the value corresponding to the amplified data signal.

22. The system of claim 18, wherein the output node is coupled to a latch, and pre-charging the sense node increases, on at least some occasions, a speed at which the value corresponding to the amplified data signal is stored in the latch.

23. The system of claim 18, wherein the buffer memory includes a latch.

24. The system of claim 18, further comprising a feedback circuit arranged to generate, based at least in part on the data signal, a feedback signal that is applied at a gate of the transistor.
